(19) United States
(12) Patent Application Publication
(10) Pub. No.: US 2016/0218157 A1
(43) Pub. Date: Jul. 28, 2016

(54) ORGANIC LIGHT EMITTING DIODE DISPLAY

(71) Applicant: Samsung Display Co., Ltd., Yongin-City (KR)

(72) Inventor: Seon Hong Ahn, Suwon-si (KR)

(21) Appl. No.: 14/749,083

(22) Filed: Jun. 24, 2015

(30) Foreign Application Priority Data
Jan. 26, 2015 (KR) 10-2015-0012145

(51) Int. Cl. H01L 27/32

(52) U.S. Cl. CPC H01L 27/3246; H01L 27/3262; H01L 27/3232

(57) ABSTRACT

An exemplary embodiment provides an organic light emitting diode display, including: a first substrate; a switching and driving thin film transistor disposed on the first substrate; a pixel electrode connected to the driving thin film transistor; a pixel defined layer disposed on an edge portion of the pixel electrode and the planarization layer and including an opening through which the pixel electrode is exposed; an organic emission layer disposed on the pixel electrode within the opening; a common electrode formed on the organic emission layer, wherein the pixel defined layer includes at least one of a thermo-chromic pigment, an organic black pigment, and a dye and a base resin.

### CROSS-REFERENCE TO RELATED APPLICATION

Any and all applications for which a foreign or domestic priority claim is identified in the Application Data Sheet as filed with the present application are hereby incorporated by reference under 37 CFR 1.57.

This application claims priority to and the benefit of Korean Patent Application No. 10-2015-0012145 filed in the Korean Intellectual Property Office on Jan. 26, 2015, the entire contents of which are incorporated herein by reference.

### BACKGROUND

1. Field

The present disclosure relates to an organic light emitting diode (OLED) display.

2. Description of the Related Technology

An OLED display includes two electrodes and an organic emission layer disposed therebetween and forms excitons by combining electrons injected from one electrode with holes injected from another electrode at the organic emission layer and emits light by allowing the excitons to emit energy. The organic light emitting device displays a predetermined image using the emission.

The OLED display has self-luminance characteristics and unlike a liquid crystal display, does not need a separate light source and therefore may have a reduced thickness and weight. Further, the OLED display demonstrates high quality characteristics, such as low power consumption, high luminance, high response speed, and therefore has drawn much attention as a next-generation display device.

The OLED display includes an organic light emitting diode, in which the organic light emitting diode includes an anode, a cathode, and an organic emission layer which is positioned between the anode and the cathode.

Meanwhile, external light is incident on the OLED display and the incident light may be reflected from the anode or the cathode. In this case, the reflected light acts as noise and a reduction in a contrast ratio of the OLED display occurs, which leads to reduction in an image quality.

### SUMMARY

The present disclosure has been made in an effort to provide an OLED display capable of preventing light incident on a side of a wiring from the outside from being reflected.

An exemplary embodiment provides an OLED display, including: a first substrate; a switching and driving thin film transistor disposed on the first substrate; a pixel electrode connected to the driving thin film transistor; a pixel defined layer disposed on an edge portion of the pixel electrode and the planarization layer and including an opening through which the pixel electrode is exposed; an organic emission layer disposed on the pixel electrode within the opening; a common electrode formed on the organic emission layer, wherein the pixel defined layer includes at least one of a thermo-chromic pigment, an organic black pigment, a dye, and a base resin.

The pixel defined layer may have a dielectric constant of 5 or less and transmittance of about 0% to about 77%.

The base resin may include at least one of photosensitive polyimide, photosensitive polybenzoxazole, and photosensitive polyacrylate.

The OLED display may further include: a spacer disposed on the pixel defined layer.

The spacer and the pixel defined layer may be made of the same material.

The planarization layer and the pixel defined layer may be made of the same material.

The pixel defined layer may include a first pixel defined layer and a second pixel defined layer which is disposed on the first pixel defined layer.

A thickness of the first pixel defined layer may range from 1.5 μm to 3 μm.

The first pixel defined layer may have a dielectric constant of 5 or less and transmittance of about 0% to about 77%.

The first pixel defined layer may include at least one of the thermo-chromic pigment, the organic black pigment, the dye, and the base resin.

The base resin may include at least one of photosensitive polyimide, photosensitive polybenzoxazole, and photosensitive polyacrylate.

The second pixel defined layer may include at least one of the photosensitive polyimide, the photosensitive polybenzoxazole, and the photosensitive polyacrylate.

The spacer and the second pixel defined layer may be made of the same material.

The planarization layer and the first pixel defined layer may be made of the same material.

According to an exemplary embodiment, it is possible to prevent the light incident from the outside from being reflected by adding at least one of the thermo-chromic pigment, the organic black pigment, and the dye to the pixel defined layer

Therefore, it is possible to prevent the deterioration in the image quality of the OLED display.

### BRIEF DESCRIPTION OF THE DRAWINGS

FIG. 1 is an equivalent circuit diagram of one pixel of an OLED display according to an exemplary embodiment.

FIG. 2 is a layout view of one pixel of the OLED display according to the exemplary embodiment.

FIG. 3 is a cross-sectional view of the OLED display of FIG. 2 taken along the line III-III.

FIG. 4 is a graph illustrating transmittance depending on a wavelength of a first pixel defined layer including a base resin and a thermo-chromic pigment and a wavelength of a layer including only the base resin.

FIG. 5 is a graph illustrating transmittance depending on a wavelength of a first pixel defined layer including a base resin and an organic black pigment and a wavelength of a layer including only the base resin.

FIG. 6 is a graph illustrating transmittance depending on a wavelength of a first pixel defined layer including a base resin and a dye and a wavelength of a layer including only the base resin.

FIG. 7 is a diagram illustrating an example of a section of an OLED display according to another exemplary embodiment.

### DETAILED DESCRIPTION

As the disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure. As used herein, the term “and/or” includes any and all combinations of one or more of the associated listed items.

Embodiments of the present disclosure will be described below in more detail with reference to the accompanying drawings. Those components that are the same or are in correspondence are rendered the same reference numeral regardless of the figure number, and redundant explanations are omitted.

It will be understood that although the terms “first”, “second”, etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

In the drawings, the thickness of layers, films, panels, regions, etc., are exaggerated for explanation. In other words, since sizes and thicknesses of components in the drawings are arbitrarily illustrated for convenience of explanation, the following embodiments are not limited thereto. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on plane” means viewing an object portion from the top and the word “on section” means viewing a section of an object portion, which is vertically taken along, from a side.

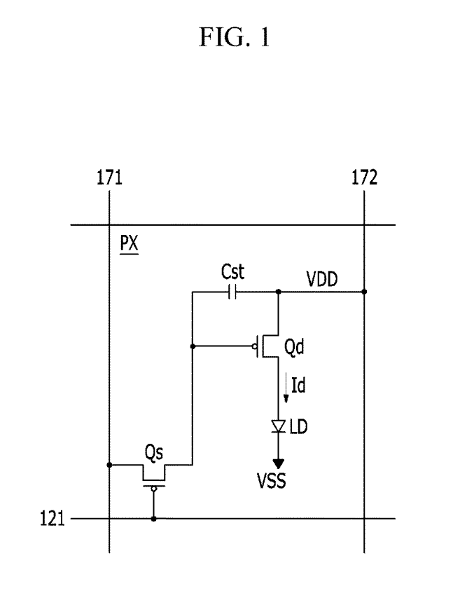

Next, the organic light emitting device according to an exemplary embodiment will be described with reference to FIGS. 1 to 3.

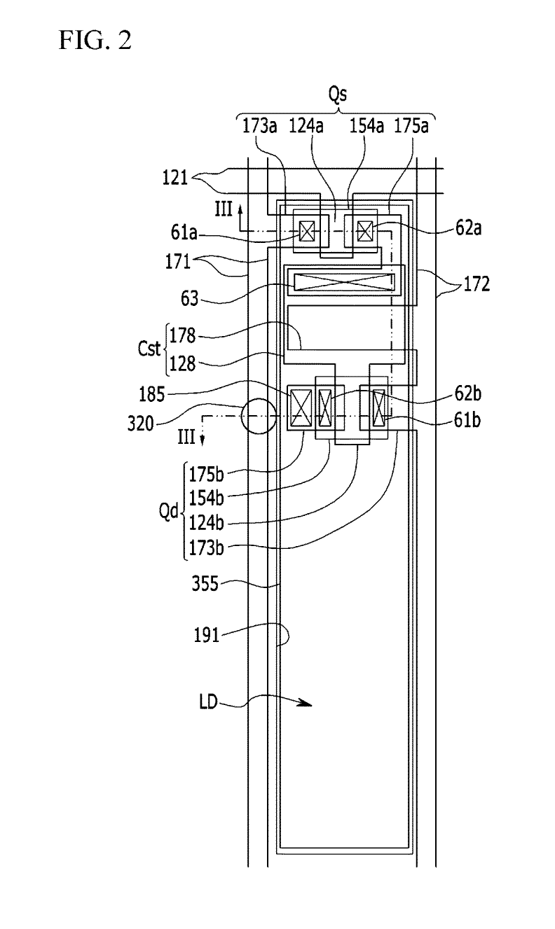

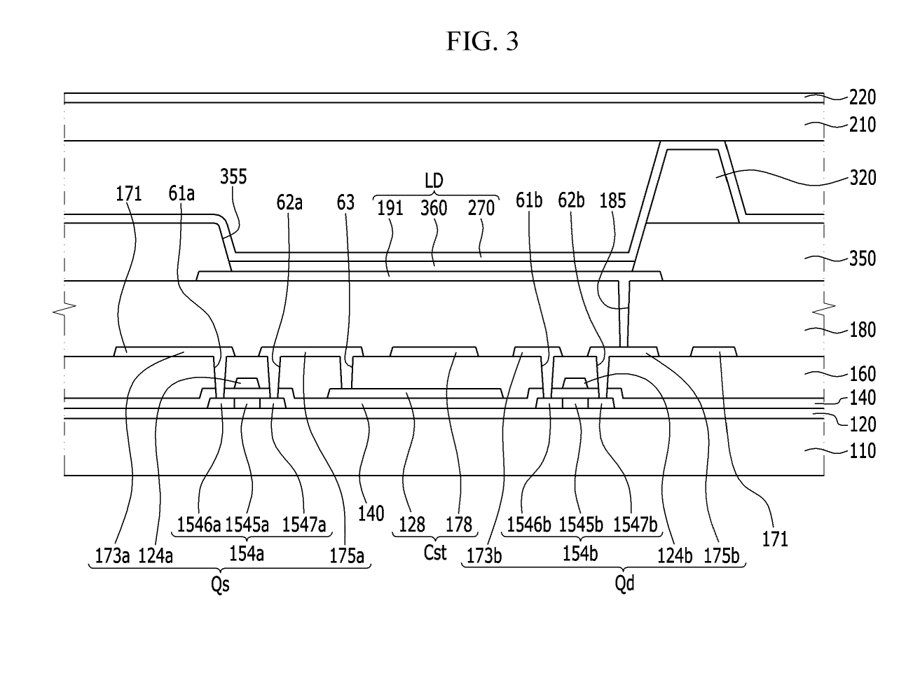

FIG. 1 is an equivalent circuit diagram of one pixel of an OLED display according to an exemplary embodiment. FIG. 2 is a layout view of one pixel of the OLED display according to the exemplary embodiment. FIG. 3 is a cross-sectional view of the OLED display of FIG. 2 taken along the line III-III.

Referring to FIG. 1, the OLED display according to the exemplary embodiment includes a plurality of signal lines 121, 171, and 172 and pixels PXs which are connected to the signal lines and are arranged in approximately a matrix form.

The signal line includes a gate line 121 which transfers a gate signal (or scan signal), a data line 171 which transfers a data signal, and a driving voltage line 172 which transfers a driving voltage VDD.

The gate line 121 approximately extends in a row direction and is approximately parallel with each other and the data line 171 and the driving voltage line 172 approximately extend in a column direction and are approximately parallel with each other.

The pixel PX includes a switching thin film transistor Qs, a driving thin film transistor Qd, a storage capacitor Cst, and an organic light emitting diode LD.

The switching thin film transistor Qs includes a control terminal, an input terminal, and an output terminal, in which the control terminal is connected to the gate line 121, the input terminal is connected to the data line 171, and the output terminal is connected to the driving thin film transistor Qd. The switching thin film transistor Qs transfers the data signal applied to the data line 171 to the driving thin film transistor Qd in response to the gate signal applied to the gate line 121.

The driving thin film transistor Qd also have a control terminal, an input terminal, and an output terminal, in which the control terminal is connected to the switching thin film transistor Qs, the input terminal is connected to the driving voltage line 172, and the output terminal is connected to the organic light emitting diode LD. The driving thin film transistor Qd transfers an output current Id of which a magnitude varies depending on a voltage applied between the control terminal and the output terminal.

The storage capacitor Cst is connected between the control terminal and the input terminal of the driving thin film transistor Qd. The storage capacitor Cst charges the data signal applied to the control terminal of the driving thin film transistor Qd and maintains the charged data signal even after the switching thin film transistor Qs is turned off.

The organic light emitting diode LD has an anode connected to the output terminal of the driving thin film transistor Qd and a cathode connected to a common voltage Vss. The organic light emitting diode LD displays an image by emitting light of which the strength varies depending on the output current Id of the driving thin film transistor Qd.

The switching thin film transistor Qs and the driving thin film transistor Qd may be an n-channel field effect transistor (FET) or a p channel field effect transistor. Further, a connection relationship among the switching and driving thin film transistors Qs and Qd, the storage capacitor Cst, and the organic light emitting diode LD may be changed.

Referring to FIGS. 2 and 3, the OLED display according to the exemplary embodiment includes a plurality of thin film structures which are disposed on the substrate 110. Hereinafter, the plurality of thin film structures will be described in detail.

A buffer layer 120 is formed on the substrate 110. The substrate 110 may be a transparent insulating substrate which is made of glass, quartz, ceramic, plastic, or the like. Further, the substrate 110 may be a metallic substrate made of stainless steel, and the like.

The buffer layer 120 may have a single layer structure made of silicon nitride (SiNx) or a double layer structure in which silicon nitride (SiNx) and silicon oxide SiO₂ are stacked. The buffer layer 120 serves to planarize a surface while preventing permeation of unnecessary components, such as impurities and moisture.

The switching semiconductor layer 154a and the driving semiconductor layer 154b are disposed on the buffer layer 120, being spaced apart from each other. The switching semiconductor layer 154a is made of polycrystalline silicon and includes a switching channel region 1545a, a switching source region 1546a, and a switching drain region 1547a. The driving semiconductor layer 154b is made of polycrystalline silicon and includes a driving channel region 1545b, a driving source region 1546b, and a driving drain region 1547b. Here, the switching source region 1546a and the switching drain region 1547a are disposed at both sides of the switching channel region 1545a and the driving source region 1546b and the driving drain region 1547b are disposed at both sides of the driving channel region 1545b.

The switching and driving channel region 1545a and 1545b are made of polycrystalline silicon which is not doped with an impurity, that is, an intrinsic semiconductor and the switching and driving source regions 1546a and 1546b and the switching and driving drain regions 1547a and the 1547b made of polycrystalline silicon which is doped with a conductive impurity, that is an impurity semiconductor.

The gate insulating layer 140 is disposed on the buffer layer 120, the switching semiconductor layer 154a, and the driving semiconductor layer 154b. The gate insulating layer 140 may be a single layer or a plurality of layers including at least one of silicon nitride and silicon oxide.

The gate line 121 and the first storage plate of electricity 128 are disposed on the gate insulating layer 140.

The gate line 121 extends in a horizontal direction to transfer the gate signal and includes a switching gate electrode 124a which protrudes from the gate line 121 to the switching semiconductor layer 154a. Here, the switching gate electrode 124a overlaps the switching channel region 1545a.

The first storage plate of electricity 128 includes the driving gate electrode 124b which protrudes from the first storage plate of electricity 128 to the driving semiconductor layer 154b. Here, the driving gate electrode 124b overlaps the driving channel region 1545b.

The interlayer insulating layer 160 is disposed on the gate line 121, the first storage plate of electricity 128, and the buffer layer 120. The interlayer insulating layer 160 may be a single layer or a plurality of layers including at least one of silicon nitride and silicon oxide.

The interlayer insulating layer 160 and the gate insulating layer 140 are provided with a switching source exposure hole 61a and a switching drain exposure hole 62a through which the switching source region 1546a and the switching drain region 1547a are each exposed. Further, the interlayer insulating layer 160 and the gate insulating layer 140 are provided with a driving source exposure hole 61b and a driving drain exposure hole 62b through which the driving source region 1546b and the driving drain region 1547b are each exposed. Further, the interlayer insulating layer 160 is provided with a first contact hole 63 through which a portion of the first storage plate of electricity 128 is exposed.

The data line 171, the driving voltage line 172, the switching drain electrode 175a, and the driving drain electrode 175b are disposed on the interlayer insulating layer 160.

The data line 171 includes a switching source electrode 173a which transfers the data signal, extends in an intersecting direction with the gate line 121, and protrudes toward the switching semiconductor layer 154a from the data line 171.

The driving voltage line 172 transfers the driving voltage, is separated from the data line 171, and extends in the same direction as the data line 171. The driving voltage line 172 includes the driving source electrode 173b which protrudes toward the driving semiconductor layer 154b from the driving voltage line 172 and a second storage plate of electricity 178 which protrudes from the driving voltage line 172 to overlap the first storage plate of electricity 128. Here, the first storage plate of electricity 128 and the second storage plate of electricity 178 form the storage capacitor Cst using the interlayer insulating layer 160 as a dielectric material.

The switching drain electrode 175a faces the switching source electrode 173a and the driving drain electrode 175b faces the driving source electrode 173b.

The switching source electrode 173a and the switching drain electrode 175a are each connected to the switching source region 1546a and the switching drain region 1547a through the switching source exposure hole 61a and the switching drain exposure hole 62a. Further, the switching drain electrode 175a is electrically connected to the first storage plate of electricity 128 and the driving gate electrode 124b through the first contact hole 63 which extends to be formed in the interlayer insulating layer 160.

The driving source electrode 173b and the driving drain electrode 175b are each connected to the driving source region 1546b and the driving drain region 1547b through the driving source exposure hole 61b and the driving drain exposure hole 62b.

The switching semiconductor layer 154a, the switching gate electrode 124a, the switching source electrode 173a, and the switching drain electrode 175a form the switching thin film transistor Qs and the driving semiconductor layer 154b, the driving gate electrode 124b, the driving source electrode 173b, and the driving drain electrode 175b form the driving thin film transistor Qd.

A passivation layer 180 is disposed on the interlayer insulating layer 160, the data line 171, the driving voltage line 172, the switching drain electrode 175a, and the driving drain electrode 175b. The planarization layer 180 may be made of an organic material and an upper surface thereof is planarized. The passivation layer 180 is provided with a second contact hole 185 through which the driving drain electrode 175b is exposed.

The organic light emitting diode LD and the pixel defined layer 350 are disposed on the passivation layer 180.

The organic light emitting diode LD includes a pixel electrode 191, an organic emission layer 360, and a common electrode 270.

The pixel electrode 191 is disposed on the passivation layer 180 and is electrically connected to the driving drain electrode 175b of the driving thin film transistor Qd through the second contact hole 185 formed on the planarization layer 180. The pixel electrode 191 is an anode of the organic light emitting diode LD.

The pixel electrode 191 may be made of a reflective metal such as lithium (Li), calcium (Ca), lithium fluoride/calcium (LiF/Ca), lithium fluoride/aluminum (LiF/Al), aluminum (Al), silver (Ag), magnesium (Mg), and gold (Au).

The pixel defined layer 350 is disposed on an edge portion of the pixel electrode 191 and the planarization layer 180, and comprises an opening 355 exposing the pixel electrode 191. That is, the edge portion of the pixel electrode 191 is positioned beneath the pixel defined layer 350.

The pixel defined layer 350 has a dielectric constant of 5 or less and transmittance of 0 to 70%. The pixel defined layer 350 may reduce the incident quantity of light from the outside. Therefore, the light from the outside which is reflected by the pixel electrode 191 which is positioned beneath the pixel defined layer 350 may be reduced. Therefore, it is possible to prevent an image quality of the OLED display from deteriorating.

The pixel defined layer 350 includes a base resin and a thermo-chromic pigment. The base resin includes photosensitive polyimide (PI), photosensitive polybenzoxazole, or photosensitive polyacrylate. The pixel defined layer 350 is formed by applying, exposing, and hardening a mixture of the base resin and the thermo-chromic pigment and has a black color due to a chemical reaction of an electron acceptor with an electron donor included in the thermo-chromic pigment by temperature at the time of hardening. Therefore, the pixel defined layer 350 has low transmittance.

The pixel defined layer 350 includes a base resin and a thermo-chromic pigment. The base resin includes photosensitive polyimide (PI), photosensitive polybenzoxazole, or photosensitive polyacrylate.

Further, the pixel defined layer 350 may include a silver base resin and an organic black pigment.

Further, the pixel defined layer 350 may include the silver base resin and a dye. Here, the dye indicates a generally used dye.

Meanwhile, the planarization layer 180 may be made of the same material as that of the pixel defined layer 350. In this case, it is possible to reduce the change of material at the time of the manufacturing process.

A spacer 320 is disposed on the pixel defined layer 350. The spacer 320 and the pixel defined layer 350 may be made of the same material. That is, the spacer 320 and the pixel defined layer 350 may be formed using the same mask.

The organic emission layer 360 is disposed on the pixel electrode 191 within the opening 355 of the pixel defined layer 350.

The organic emission layer 360 is formed of a plurality of layers which include at least one of a light emitting layer, a hole-injection layer (HIL), a hole-transporting layer (HTL), an electron-transporting layer (ETL), and an electron-injection layer (EIL). When the organic emission layer 360 includes both of them, the hole injection layer is disposed on the pixel electrode 191 which is the anode and the hole transport layer, the light emitting layer, the electron transport layer, and the electron injection layer may be stacked thereon.

The organic emission layer 360 may include a red organic emission layer which emits red light, a green organic emission layer which emits green light, and a blue organic emission layer which emits blue light, in which the red organic emission layer, the green organic emission layer, and the blue organic emission layer are each formed in a red pixel, a green pixel, and a blue pixel to implement a color image.

Further, the organic emission layer 360 may implement the color image by stacking the red organic emission layer, the green organic emission layer, and the blue organic emission layer in all of the red pixel, the green pixel, and the blue pixel and forming a red filter, a green filter, and a blue filter for each pixel. As another example, the color image may be implemented by forming a white organic emission layer which emits white light in all of the red pixel, the green pixel, and the blue pixel and forming the red filter, the green filter, and the blue filter for each pixel. At the time of implementing the color image using the white organic emission layer and the color filters, there is no need to use a deposition mask for depositing the red organic emission layer, the green organic emission layer, and the blue organic emission layer on each pixel, that is, the red pixel, the green pixel, and the blue pixel.

The white organic emission layer described in another example may be formed of a single organic emission layer and may be configured to emit white light by stacking the plurality of organic emission layers. For example, the white organic emission layer may also include a configuration to emit white light by combining at least one yellow organic emission layer with at least one blue organic emission layer, a configuration to emit white light by combining at least one cyan organic emission layer with at least one red organic emission layer, and a configuration to emit white light by combining at least one magenta organic emission layer with at least one green organic emission layer, and the like.

The common electrode 270 is disposed on the pixel defined layer 350, the spacer 320, and the organic emission layer 360. The common electrode 270 may be made of transparent conductive materials, such as ITO, IZO, ZnO or In₂O₃. The common electrode 270 is a cathode of the organic light emitting diode LD.

The second substrate 210 is disposed on the spacer 320. The second substrate 210 is bonded to the first substrate 110 by a sealant (not illustrated) and serves as an encapsulation substrate. In this case, the spacer 320 serves to maintain an interval between the first substrate 110 and second substrate 210.

A polarizer 220 is formed on the second substrate 210. The polarizer 220 polarizes light emitted from the organic light emitting diode LD.

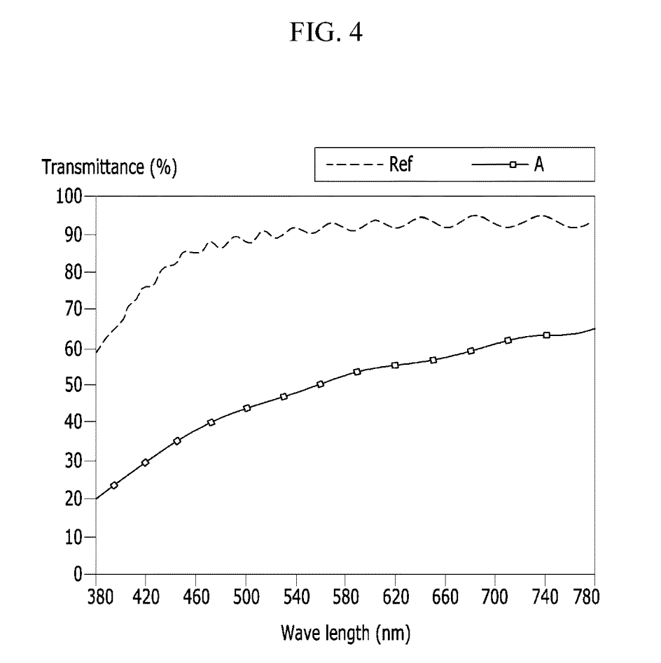

Next, characteristics of the first pixel defined layer according to the exemplary embodiment will be described in detail with reference to FIGS. 4 to 6.

FIG. 4 is a graph illustrating transmittance depending on a wavelength of a first pixel defined layer including a base resin and a thermo-chromic pigment and a wavelength of a layer including only the base resin.

It may be appreciated from FIG. 4 that the transmittance of the first pixel defined layer including the base resin and the thermo-chromic pigment is much more reduced than that of the layer including only the base resin.

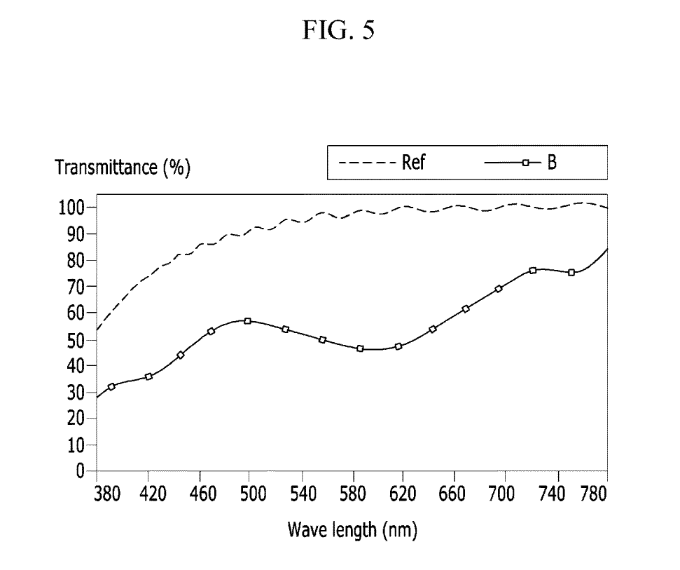

FIG. 5 is a graph illustrating transmittance depending on a wavelength of a first pixel defined layer including a base resin and an organic black pigment and a wavelength of a layer including only the base resin.

It may be appreciated from FIG. 5 that the transmittance of the first pixel defined layer including the base resin and the organic black pigment is much more reduced than that of the layer including only the base resin.

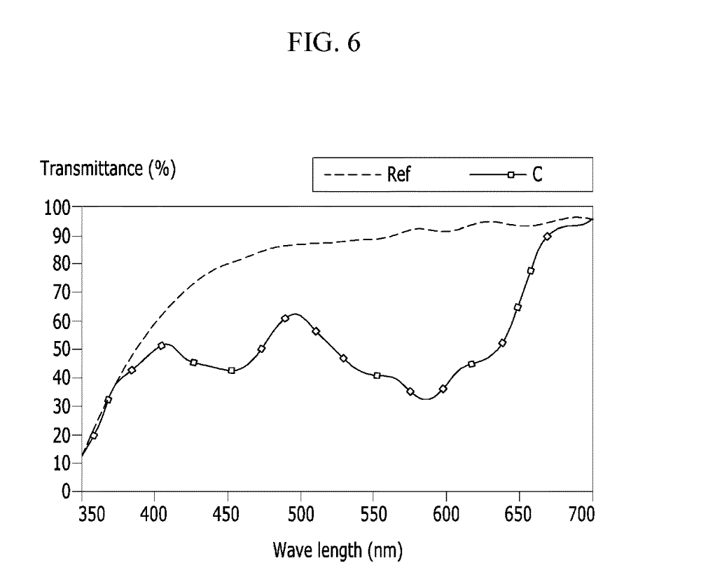

FIG. 6 is a graph illustrating transmittance depending on a wavelength of a first pixel defined layer including a base resin and a dye and a wavelength of a layer including only the base resin.

It may be appreciated from FIG. 6 that the transmittance of the first pixel defined layer including the base resin and the dye is much more reduced than that of the layer including only the base resin.

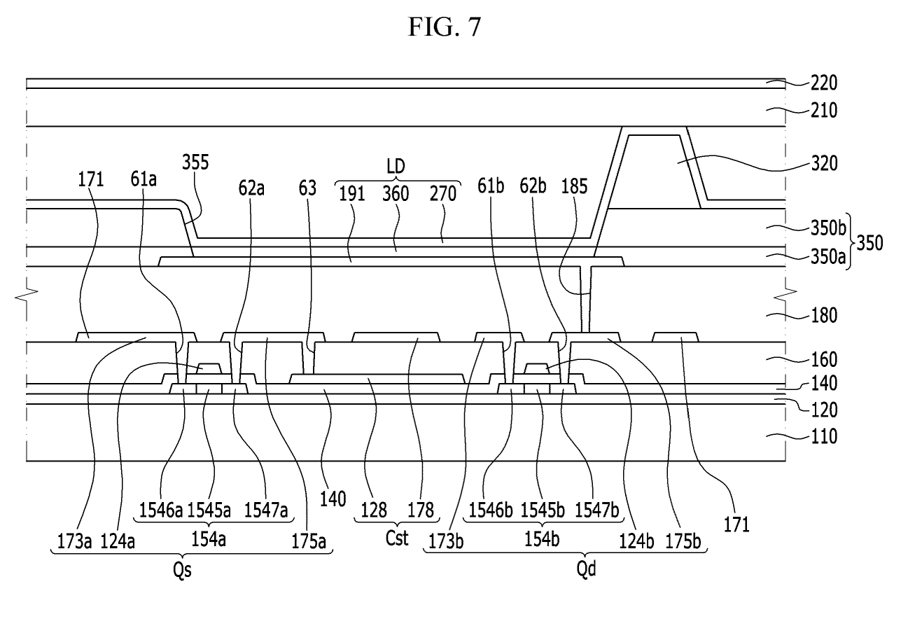

Next, an OLED display according to another exemplary embodiment will be described with reference to FIG. 7.

FIG. 7 is a diagram illustrating an example of a section of an OLED display according to another exemplary embodiment.

Referring to FIG. 7, the OLED display according to the exemplary embodiment has the same configuration as the OLED display illustrated in FIG. 2, except for the configuration of the pixel defined layer and the spacer. Therefore, the description of the same configuration will be omitted.

The pixel defined layer 350 of the OLED display illustrated in FIG. 7 is configured of two layers, unlike the configuration of the pixel defined layer 350 of the OLED display illustrated in FIG. 2. The pixel defined layer 350 is provided with an opening 355 through which the pixel electrode 191 is exposed.

The pixel defined layer 350 includes a first pixel defined layer 350a and a second pixel defined layer 350b which is disposed on the first pixel defined layer 350a.

The first pixel defined layer 350a is disposed on an edge portion of the pixel electrode 191 and the passivation layer 180. The edge portion of the pixel electrode 191 is positioned beneath the first pixel defined layer 350a.

The first pixel defined layer 350a has a dielectric constant of 5 or less, transmittance of 0% to 70%, and a thickness of 1.5 μm to 3 μm. The first pixel defined layer 350a may reduce the incident quantity of light from the outside. Therefore, the light from the outside which is reflected by the pixel electrode 191 which is positioned beneath the first pixel defined layer 350a may be reduced.

The first pixel defined layer 350a includes the base resin and the thermo-chromic pigment. The base resin includes photosensitive polyimide (PI), photosensitive polybenzoxazole, or photosensitive polyacrylate. The pixel defined layer 350 is formed by applying, exposing, and hardening a mixture of the base resin and the thermo-chromic pigment and has a black color due to a chemical reaction of an electron acceptor with an electron donor included in the thermo-chromic pigment by temperature at the time of hardening. Therefore, the first pixel defined layer 350a has low transmittance. Therefore, it is possible to prevent an image quality of the OLED display from deteriorating.

Further, the first pixel defined layer 350a may include a base resin and an organic black pigment.

Further, the first pixel defined layer 350a may include the base resin and a dye. Here, the dye indicates a generally used dye.

The second pixel defined layer 350b includes photosensitive polyimide (PI), photosensitive polybenzoxazole, or photosensitive polyacrylate.

Meanwhile, the planarization layer 180 may also be made of the same material as that of the first pixel defined layer 350a. In this case, it is possible to reduce the change of material at the time of the manufacturing process.

The spacer 320 is disposed on the pixel defined layer 350. The spacer 320 and the second pixel defined layer 350b may be made of the same material. That is, the spacer 320 and the second pixel defined layer 350b may be formed using the same mask.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present disclosure as defined by the following claims

What is claimed is:

1. An organic light emitting diode display (OLED), comprising:
a first substrate;
a switching and driving thin film transistor disposed on the first substrate;
a pixel electrode connected to the driving thin film transistor;
a pixel defined layer disposed on an edge portion of the pixel electrode and the planarization layer and including an opening through which the pixel electrode is exposed;
an organic emission layer disposed on the pixel electrode within the opening; and
a common electrode formed on the organic emission layer,
wherein the pixel defined layer includes at least one of a thermo-chromic pigment, an organic black pigment, and a dye and a base resin.

2. The OLED display of claim 1, wherein the pixel defined layer has a dielectric constant of 5 or less and transmittance of about 0% to about 77%.

3. The OLED display of claim 2, wherein the base resin includes at least one of photosensitive polyimide, photosensitive polybenzoxazole, and photosensitive polyacrylate.

4. The OLED display of claim 3, further comprising a spacer disposed on the pixel defined layer.

5. The OLED display of claim 4, wherein the spacer and the pixel defined layer are made of the same material.

6. The OLED display of claim 1, wherein the planarization layer and the pixel defined layer are made of the same material.

7. The OLED display of claim 1, wherein the pixel defined layer includes a first pixel defined layer and a second pixel defined layer which is disposed on the first pixel defined layer.

8. The OLED display of claim 7, wherein a thickness of the first pixel defined layer ranges from 1.5 μm to 3 μm.

9. The OLED display of claim 8, wherein the first pixel defined layer has a dielectric constant of 5 or less and transmittance of about 0% to about 77%.

10. The OLED display of claim 9, wherein the first pixel defined layer includes at least one of the thermo-chromic pigment, the organic black pigment, and the dye and the base resin.

11. The OLED display of claim 10, wherein the base resin includes at least one of photosensitive polyimide, photosensitive polybenzoxazole, or photosensitive polyacrylate.

12. The OLED display of claim 11, wherein the second pixel defined layer includes at least one of the photosensitive polyimide, the photosensitive polybenzoxazole, and the photosensitive polyacrylate.

13. The OLED display of claim 12, further comprising a spacer disposed on the pixel defined layer.

14. The OLED display of claim 13, wherein the spacer and the second pixel defined layer are made of the same material.

15. The OLED display of claim 7, wherein the planarization layer and the first pixel defined layer are made of the same material.
